(19) United States
(12) Patent Application Publication
(10) Pub. No.: US 2010/0295131 A1
(43) Pub. Date: Nov. 25, 2010

(54) SEMICONDUCTOR DEVICE AND MANUFACTURING METHOD OF SEMICONDUCTOR DEVICE

(75) Inventor: Kentaro Eda, Oita (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/725,002

(22) Filed: Mar. 16, 2010

(30) Foreign Application Priority Data
May 19, 2009 (JP) 2009-121163

(51) Int. Cl. H01L 29/78; H01L 29/06; H01L 21/762

(52) U.S. Cl. 257/368; 257/506; 438/425; 257/E29.02; 257/E29.255; 257/E21.546

(57) ABSTRACT

A buried insulating layer is buried at a position lower than a surface of a semiconductor substrate, and a cap insulating layer, which is made of a material different from the buried insulating layer, is formed on the buried insulating layer not to protrude into a shoulder portion of a step between the semiconductor substrate and the buried insulating layer.

### CROSS-REFERENCE TO RELATED APPLICATIONS

This application is based upon and claims the benefit of priority from the prior Japanese Patent Application No. 2009-121163, filed on May 19, 2009; the entire contents of which are incorporated herein by reference.

### BACKGROUND OF THE INVENTION

1. Field of the Invention

The present invention relates to a semiconductor device and a manufacturing method of the semiconductor device, and is particularly suitably applied to a shallow trench isolation (STI) structure used for isolation.

2. Description of the Related Art

An STI structure is used in some cases for electrically insulating a semiconductor element formed on a semiconductor substrate. This STI structure realizes isolation by burying an insulator in a trench formed in the semiconductor substrate, and is excellent in miniaturization of an isolation structure compared with the Local Oxidation of Silicon (LOCOS) method.

Moreover, for example, Japanese Patent Application Laid-open No. 2002-299433 discloses a method of forming an isolation film in a silicon substrate by forming a cap layer on an upper surface of the whole structure including an insulating material film buried in a trench region, selectively removing part of the cap layer to selectively expose an upper surface of a part of the insulating material film formed in the upper portion in a region other than the trench region, and selectively removing the insulating material film of which upper surface is exposed.

However, in the conventional STI structure, the surface of the STI structure is retracted through etching processing and the like after the STI structure is formed, so that a step with respect to the semiconductor substrate increases. Therefore, a side surface of the semiconductor substrate at the boundary with the STI structure is exposed, which may be a factor in causing a junction leakage and result in forming a void at a step portion when an inter-layer insulating layer is formed on the STI structure to decease a short margin between contact electrodes buried in the inter-layer insulating layer.

Moreover, the method disclosed in Japanese Patent Application Laid-open No. 2002-299433 has a problem in that the cap layer protrudes outside the trench region, so that a region of the isolation structure increases, thereby hindering miniaturization of the isolation structure.

### BRIEF SUMMARY OF THE INVENTION

A semiconductor device according to an embodiment of the present invention comprises: a semiconductor substrate; a buried insulating layer that is buried at a position lower than a surface of the semiconductor substrate; and a cap insulating layer that is formed on the buried insulating layer not to protrude into a shoulder portion of a step between the semiconductor substrate and the buried insulating layer and is made of a material different from the buried insulating layer.

A method of manufacturing a semiconductor device according to an embodiment of the present invention comprises: forming a trench in a semiconductor substrate; burying a buried insulating layer in the trench at a position lower than a surface of the semiconductor substrate; forming a cap insulating layer arranged to protrude into a step between the semiconductor substrate and the buried insulating layer on the buried insulating layer; forming a resist pattern on the cap insulating layer with a step of the cap insulating layer as a boundary; removing the cap insulating layer on the semiconductor substrate by etching the cap insulating layer with the resist pattern as a mask; and removing the resist pattern on the semiconductor substrate after the removing the cap insulating layer on the semiconductor substrate.

A method of manufacturing a semiconductor device according to an embodiment of the present invention comprises: forming a trench in the semiconductor substrate; burying a buried insulating layer in the trench at a position lower than a surface of the semiconductor substrate; forming a gate electrode in an element forming region isolated by the buried insulating layer; forming an insulating layer, of which material is difference from the buried insulating layer, on the buried insulating layer, the insulating layer covering the gate electrode and the buried insulating layer and being arranged to protrude into a step between the semiconductor substrate and the buried insulating layer; forming a resist pattern, which is arranged so that the element forming region is not covered, on the insulating layer with a step of the insulating layer as a boundary; forming a cap insulating layer on the buried insulating layer and a side wall on a side face of the gate electrode by etching the insulating layer with the resist pattern as a mask; and removing the resist pattern from the cap insulating layer.

### BRIEF DESCRIPTION OF THE DRAWINGS

FIGS. 1A to 1C are cross-sectional views illustrating a schematic configuration of a semiconductor device according to a first embodiment of the present invention;

FIG. 2 is a diagram illustrating a relationship between an STI retraction amount and a resist skirt remaining film RT;

FIGS. 3A to 3D are cross-sectional views illustrating a relationship between a misalignment amount OL and the resist skirt remaining film RT of a resist pattern;

FIG. 4 is a diagram illustrating a relationship between a misalignment amount OLT at a top of the resist pattern and a misalignment amount OLE at a bottom portion of the resist pattern;

FIGS. 5A and 5B are cross-sectional views illustrating an example of a manufacturing method of a semiconductor device according to a second embodiment of the present invention;

FIGS. 6A and 6B are cross-sectional views illustrating an example of the manufacturing method of the semiconductor device according to the second embodiment of the present invention;

FIGS. 7A and 7B are cross-sectional views illustrating an example of the manufacturing method of the semiconductor device according to the second embodiment of the present invention; and

FIG. 8 is a cross-sectional view illustrating an example of the manufacturing method of the semiconductor device according to the second embodiment of the present invention.

### DETAILED DESCRIPTION OF THE INVENTION

A semiconductor device and a manufacturing method of the semiconductor device according to embodiments of the present invention are explained below with reference to the drawings. The present invention is not limited to these embodiments.

### First Embodiment

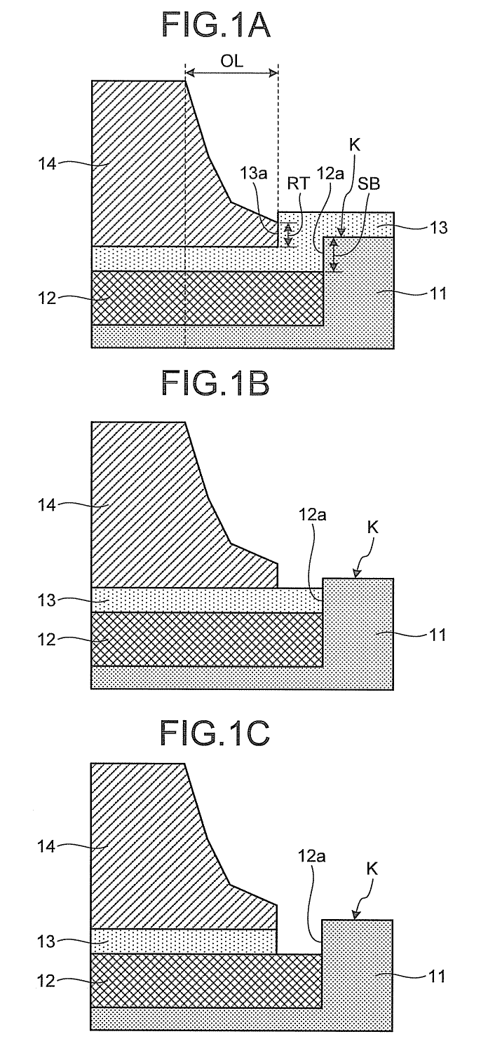

FIGS. 1A to 1C are cross-sectional views illustrating a schematic configuration of a semiconductor device according to the first embodiment of the present invention.

In FIG. 1A, a buried insulating layer 12 is buried in a region of a part of a semiconductor substrate 11. The material of the semiconductor substrate 11 can be selected from, for example, Si, Ge, SiGe, SiC, SiSn, PbS, GaAs, InP, GaP, GaN, GaAlAs, GaInAsP, and ZnSe. For example, a silicon oxide film can be used as the material of the buried insulating layer 12.

The buried insulating layer 12 is buried at a position lower than the surface of the semiconductor substrate 11, and a step 12a is formed at the boundary of the semiconductor substrate 11 and the buried insulating layer 12. A STI retraction amount SB of the surface of the buried insulating layer 12 from the surface of the semiconductor substrate 11 is preferably 30 nm or more.

A cap insulating layer 13 is laminated on the semiconductor substrate 11 and the buried insulating layer 12. A step 13a due to the step 12a at the boundary of the semiconductor substrate 11 and the buried insulating layer 12 is formed in the cap insulating layer 13. The cap insulating layer 13 can be made of a material different from the buried insulating layer 12 and is preferably made of a material with etch resistance higher than that of the buried insulating layer 12. For example, when the buried insulating layer 12 is composed of a silicon oxide film, the cap insulating layer 13 can be composed of a silicon nitride film, a silicon oxynitride film, a hafnium oxide film, an aluminum oxide film, an aluminum nitride film, a tantalum oxide film, a titanium oxide film, or a combination of these films. Moreover, the cap insulating layer 13 can have a single-layer structure or a multi-layer structure.

A resist pattern 14 is formed on the cap insulating layer 13 for selectively removing the cap insulating layer 13 on the semiconductor substrate 11 while leaving the cap insulating layer 13 on the buried insulating layer 12. Defocusing occurs at a part of the step 13a of the cap insulating layer 13 at the time of exposure for forming the resist pattern 14, so that the exposure is not performed sufficiently. Therefore, even when the alignment position of the resist pattern 14 is displaced from the position of the step 13a of the cap insulating layer 13 on the side of the buried insulating layer 12, trailing occurs with the step 13a of the cap insulating layer 13 as a boundary, so that the resist pattern 14 is self-aligned with the step 13a of the cap insulating layer 13. If the STI retraction amount SB is 30 nm or more, 20 nm or more of a resist skirt remaining film RT can be ensured at the step 13a of the cap insulating layer 13 by adjusting the exposing condition.

Then, as shown in FIG. 1B, the cap insulating layer 13 is etched with the resist pattern 14 as a mask to selectively remove the cap insulating layer 13 on the semiconductor substrate 11, whereby the cap insulating layer 13 is formed on the buried insulating layer 12 in a self-aligned manner. After the cap insulating layer 13 on the semiconductor substrate 11 is removed, overetching of the cap insulating layer 13 is suppressed, so that the end portion of the cap insulating layer 13 can be aligned with the position of the end portion of the buried insulating layer 12.

Alternatively, as shown in FIG. 1C, after the cap insulating layer 13 on the semiconductor substrate 11 is removed, the end portion of the buried insulating layer 12 can be exposed by overetching the cap insulating layer 13. In this case, the position of the end portion of the cap insulating layer 13 is misaligned from the position of the step 12a at the boundary of the semiconductor substrate 11 and the buried insulating layer 12 by the thickness of the cap insulating layer 13 formed on the side wall of the step 12a at the boundary of the semiconductor substrate 11 and the buried insulating layer 12.

Consequently, the cap insulating layer 13 can be formed on the buried insulating layer 12 in a self-aligned manner, so that the cap insulating layer 13 can be formed on the buried insulating layer without protruding into a shoulder portion K (the shoulder portion K is a upper level of the step 12a at the boundary of the semiconductor substrate 11 and the buried insulating layer 12) of the step 12a between the semiconductor substrate 11 and the buried insulating layer 12. Therefore, there is no need to ensure a margin for the misalignment when forming the cap insulating layer 13 on the buried insulating layer 12, thereby enabling to reduce the retraction amount of the surface of the isolation structure without increasing the area of the isolation structure. Thus, a junction leakage or a void due to the step 12a at the boundary of the semiconductor substrate 11 and the buried insulating layer 12 can be suppressed from occurring without hindering miniaturization of the isolation structure.

Moreover, the cap insulating layer 13 is formed on the buried insulating layer 12 in a self-aligned manner, so that distortion can be applied to the active region that is isolated by the buried insulating layer 12. Therefore, when a field-effect transistor is formed in the active region isolated by the buried insulating layer 12, mobility of the field-effect transistor can be improved, enabling to speed up the field-effect transistor. When an N-channel field-effect transistor is formed in the active region isolated by the buried insulating layer 12, a material that gives a tensile stress is preferably used for the cap insulating layer 13. When a P-channel field-effect transistor is formed in the active region isolated by the buried insulating layer 12, a material that gives a compression stress is preferably used for the cap insulating layer 13.

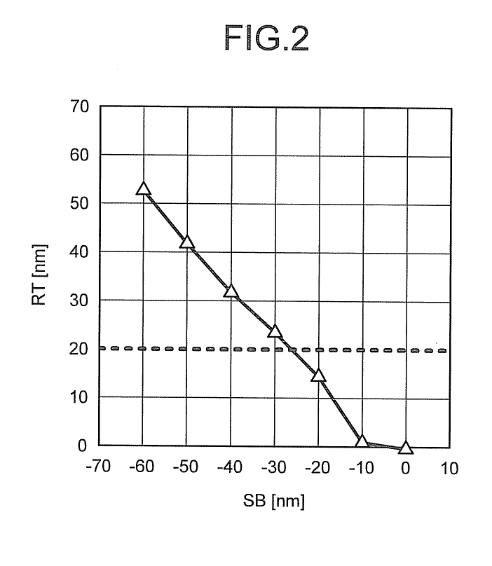

FIG. 2 is a diagram illustrating a relationship between the STI retraction amount SB and the resist skirt remaining film RT.

In FIG. 2, when a misalignment amount OL of the resist pattern 14 is −60 nm, the resist skirt remaining film RT increases with increase of the STI retraction amount SB. When the STI retraction amount SB is 30 nm or more, it is possible to ensure 20 nm or more of the resist skirt remaining film RT at the step 13a of the cap insulating layer 13 by adjusting the exposing condition.

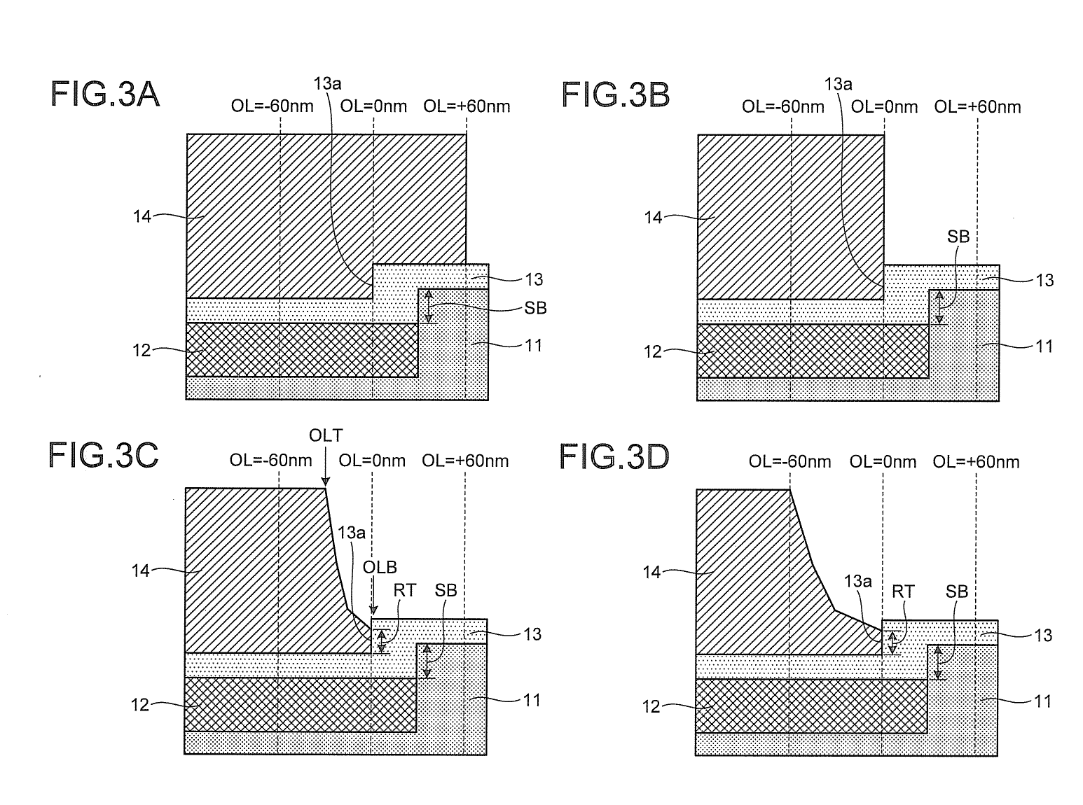

FIGS. 3A to 3D are cross-sectional views illustrating a relationship between the misalignment amount OL and the resist skirt remaining film RT of the resist pattern 14.

In FIG. 3A, when the misalignment amount OL of the resist pattern 14 is positive with the position of the step 13a of the cap insulating layer 13 as a reference, trailing of the resist pattern 14 does not occur and a misalignment amount OLT at the top of the resist pattern 14 matches a misalignment amount OLB at the bottom portion of the resist pattern 14.

Moreover, as shown in FIG. 3B, when the misalignment amount OL of the resist pattern 14 is 0, the trailing of the resist pattern 14 does not occur and the misalignment amount OLT at the top of the resist pattern 14 matches the misalignment amount OLB at the bottom portion of the resist pattern 14.

On the other hand, as shown in FIG. 3C and FIG. 3D, when the misalignment amount OL of the resist pattern 14 is negative, the misalignment amount OLT at the top of the resist pattern 14 also becomes negative; however, if the misalignment amount OL of the resist pattern 14 is within a predetermined range, the trailing occurs in the resist pattern 14. Therefore, the misalignment amount OLB at the bottom portion of the resist pattern 14 becomes 0.

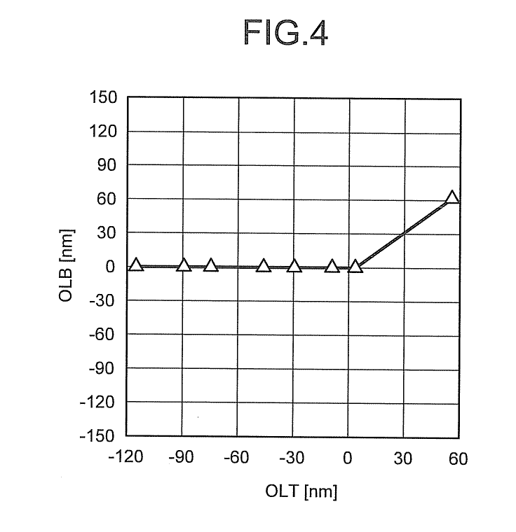

FIG. 4 is a diagram illustrating a relationship between the misalignment amount OLT at the top of the resist pattern 14 and the misalignment amount OLB at the bottom portion of the resist pattern 14.

In FIG. 4, it is found that when the misalignment amount OL of the resist pattern 14 is changed to the negative side, the misalignment amount OLT at the top of the resist pattern 14 is also changed in accordance with the amount of change thereof; however, the misalignment amount OLB at the bottom of the resist pattern 14 is not changed.

### Second Embodiment

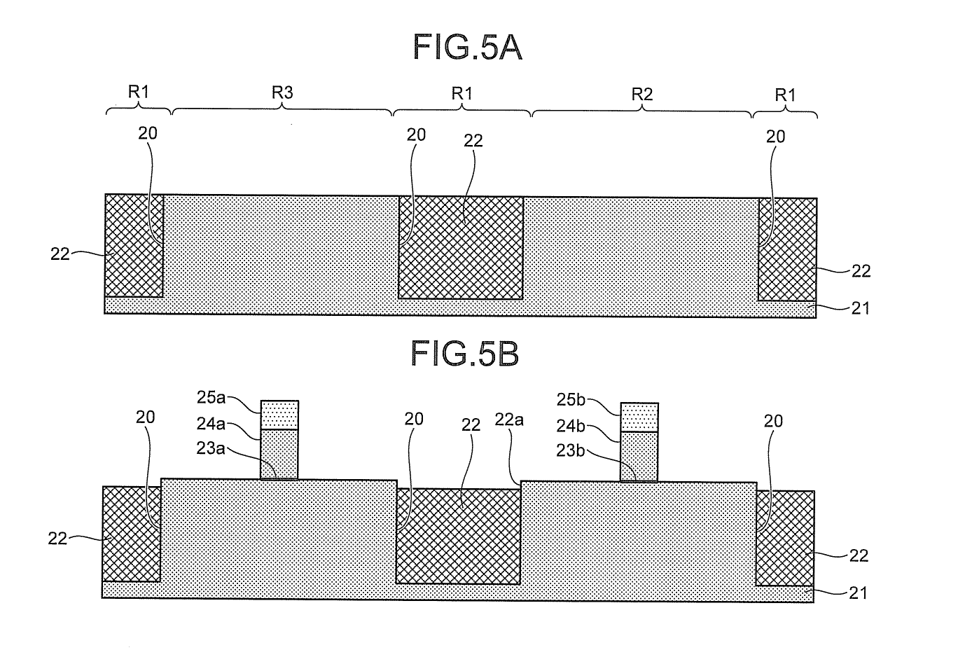

FIGS. 5A to 8 are cross-sectional views illustrating an example of a manufacturing method of a semiconductor device according to the second embodiment of the present invention.

In FIG. 5A, a semiconductor substrate 21 has an isolation region R1 and element forming regions R2 and R3. The material of the semiconductor substrate 21 can be selected from, for example, Si, Ge, SiGe, SIC, SiSn, PbS, GaAs, InP, GaP, GaN, GaAlAs, GaInAsP, and ZnSe.

A hard mask is formed on the semiconductor substrate 21 by using a method such as the Low-Pressure Chemical Vapor Deposition (LPCVD) as an example. For example, a silicon nitride film can be used as the material of the hard mask. The film thickness of the hard mask can be set to, for example, about 150 nm.

Then, the hard mask is removed from the isolation region R1 by using the photolithographic technique and the dry etching technique. Then, the semiconductor substrate 21 in the isolation region R1 from which the hard mask is removed is etched to form a trench 20 in the isolation region R1 of the semiconductor substrate 21. The depth of the trench 20 is set to, for example, about 300 nm.

Then, a buried insulating layer 22 is buried in the trench 20 to form the buried insulating layer 22 on the semiconductor substrate 21 by using a method such as the CVD as an example. Then, the buried insulating layer 22 is thinned by using a method such as the Chemical Mechanical Polishing (CMP) as an example to remove the buried insulating layer 22 in the element forming regions R2 and R3. For example, a silicon oxide film can be used as the material of the buried insulating layer 22.

When removing the buried insulating layer 22 in the element forming regions R2 and R3, the hard mask formed on the semiconductor substrate 21 can be used as a stopper. Then, after removing the buried insulating layer 22 in the element forming regions R2 and R3, the hard mask formed on the semiconductor substrate 21 is removed.

In order to align the position of the surface of the buried insulating layer 22 with the position of the surface of the semiconductor substrate 21, after removing the buried insulating layer 22 in the element forming regions R2 and R3, the hard mask can be removed after etching and removing the surface layer of the buried insulating layer 22, for example, by about 50 nm.

Next, the ion implantation of impurities such as B, As, and P is performed on the semiconductor substrate 21 and the thermal treatment is performed at 1000° C. or more, whereby P-type or N-type well region and channel region are formed.

Next, as shown in FIG. 5B, gate insulating films 23a and 23b are formed on the semiconductor substrate 21 in the element forming regions R2 and R3, respectively, by using a method such as the thermal oxidation as an example. For example, a silicon oxide film or a high-dielectric film can be used as the material of the gate insulating films 23a and 23b. The film thickness of the gate insulating films 23a and 23b is set to, for example, about 1 nm.

Then, a conductive film and an insulating film are laminated in order on the semiconductor substrate 21 on which the gate insulating films 23a and 23b are formed by using a method such as the CVD as an example. Then, the patterning is performed on the conductive film and the insulating film by using the photolithographic technique and the dry etching technique, whereby gate electrodes 24a and 24b, and hard masks 25a and 25b are formed on the semiconductor substrate 21 in the element forming regions R2 and R3 via the gate insulating films 23a and 23b, respectively. For example, a polycrystalline silicon film, metal, or alloy can be used as the material of the gate electrodes 24a and 24b. For example, a silicon oxide film or a silicon nitride film can be used as the material of the hard masks 25a and 25b. The film thickness of the gate electrodes 24a and 24b is set to, for example, about 80 nm, and the film thickness of the hard masks 25a and 25b is set to, for example, about 40 nm. When forming the gate electrodes 24a and 24b and the hard masks 25a and 25b, the buried insulating layer 22 is also etched, so that a step 22a is formed at the boundary of the semiconductor substrate 21 and the buried insulating layer 22.

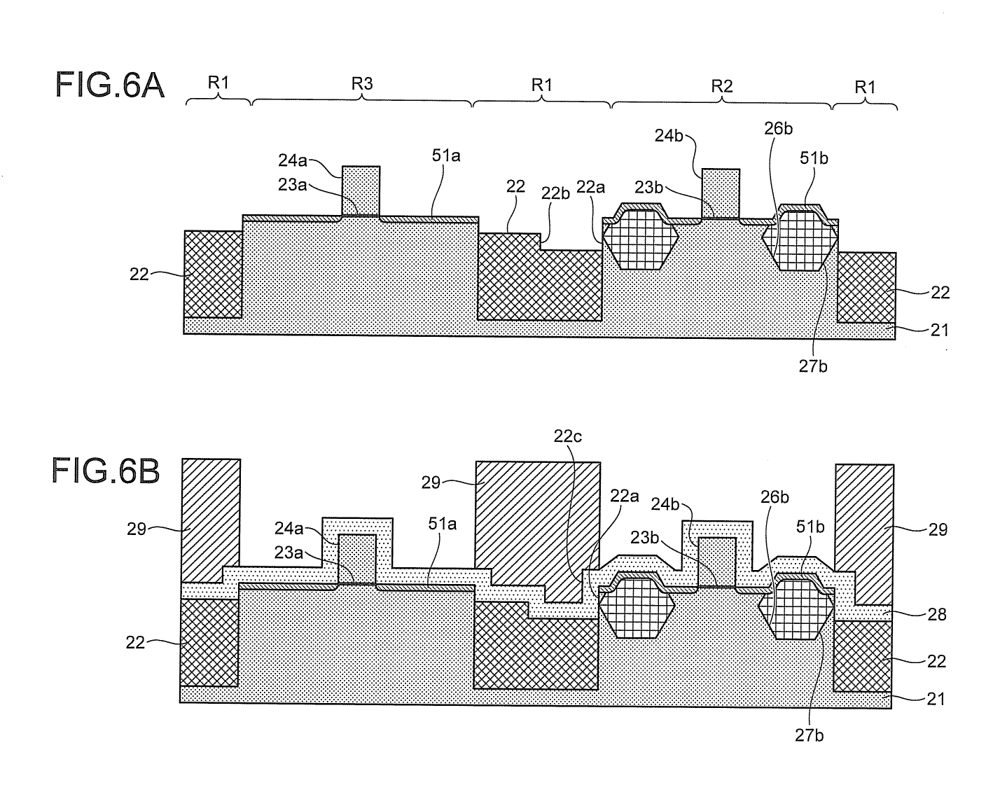

Next, as shown in FIG. 6A, the hard masks 25a and 25b on the gate electrodes 24a and 24b are removed. Then, concave portions 26b arranged on both sides of the gate electrode 24b are formed in the element forming region R2 of the semiconductor substrate 21 by using the photolithographic technique and the dry etching technique. When forming the concave portions 26b in the element forming region R2 of the semiconductor substrate 21, part of the buried insulating layer 22 is also etched, so that a step 22b is formed on the buried insulating layer 22. Therefore, the step 22a at the boundary of the semiconductor substrate 21 and the buried insulating layer 22 increases in the element forming region R2.

Then, buried semiconductor layers 27b buried in the concave portions 26b are formed on the semiconductor substrate 21 by an epitaxial growth. A material different from the material of the semiconductor substrate 21 can be selected for the buried semiconductor layer 27. For example, when the material of the semiconductor substrate 21 is Si, SiSe can be used as the material of the buried semiconductor layer 27b.

Next, the ion implantation of impurities such as B, As, and P is performed on the semiconductor substrate 21 and the buried semiconductor layers 27b with the gate electrodes 24a and 24b as a mask, and the thermal treatment is performed at 1000° C. or more, whereby LDD layers 51a and 51b that are self-aligned with the gate electrodes 24a and 24b, respectively, are formed on the semiconductor substrate 21 and the buried semiconductor layers 27b.

Next, as shown in FIG. 6B, an insulating layer 28 is formed on the semiconductor substrate 21 so that the gate electrodes 24a and 24b and the buried insulating layer 22 are covered by using a method such as the CVD as an example. The insulating layer 28 can be made of a material different from that of the buried insulating layer 22, and is preferably made of a material with etch resistance higher than that of the buried insulating layer 22. For example, when the buried insulating layer 22 is composed of a silicon oxide film, the insulating layer 28 can be composed of a silicon nitride film, a silicon oxynitride film, a hafnium oxide film, an aluminum oxide film, an aluminum nitride film, a tantalum oxide film, a titanium oxide film, or a combination of these films. Moreover, the insulating layer 28 can have a single-layer structure or a multi-layer structure. Furthermore, the film thickness of the insulating layer 28 is set to, for example, about 30 nm. A step 22c due to the step 22a at the boundary of the semiconductor substrate 21 and the buried insulating layer 22 is formed on the insulating layer 28.

Next, a resist pattern 29 arranged to correspond to the position of the buried insulating layer 22 is formed on the insulating layer 28 by using the photolithographic technique. When the resist pattern 29 is misaligned, the trailing in which the end portion is aligned with the position of the step 22c of the insulating layer 28 can occur in the resist pattern 29 by setting the alignment position of the resist pattern 29 on the side of the buried insulating layer 22. When such trailing is caused to occur in the resist pattern 29, the retraction amount of the surface of the insulating layer 28 from the surface of the semiconductor substrate 21 is preferably 30 nm or more. Moreover, in order to cause the trailing in which the end portion is aligned with the position of the step 22c of the insulating layer 28 to occur in the resist pattern 29, the exposing condition for forming the resist pattern 29 is preferably set so that defocusing occurs at part of the step 22c of the insulating layer 28.

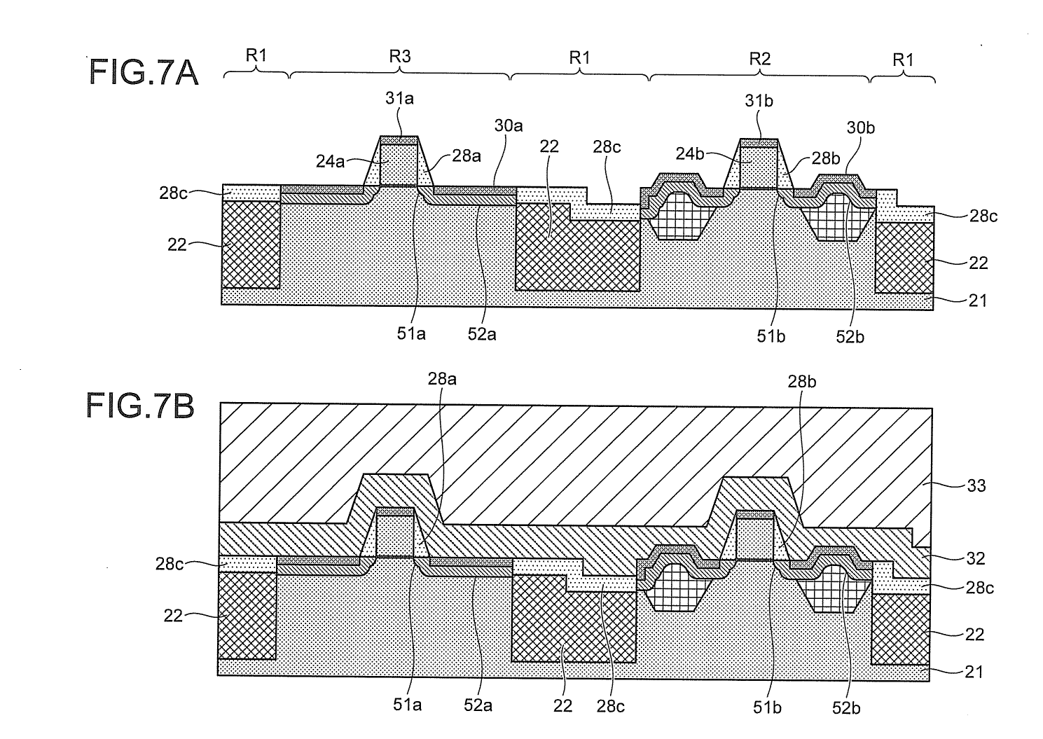

Next, as shown in FIG. 7A, the insulating layer 28 is selectively etched with the resist pattern 29 as a mask to form side walls 28a and 28b arranged on the side faces of the gate electrodes 24a and 24b, respectively, on the semiconductor substrate 21, and form a cap insulating layer 28c on the buried insulating layer 22. The resist pattern 29 is self-aligned to correspond to the position of the buried insulating layer 22, so that the cap insulating layer 28c is prevented from protruding outside the buried insulating layer 22 and the cap insulating layer 28c can be arranged on the buried insulating layer 22.

Next, the ion implantation of impurities such as B, As, and P is performed on the semiconductor substrate 21 and the buried semiconductor layers 27b with the gate electrodes 24a and 24b and the side walls 28a and 28b as a mask and the thermal treatment is performed at 1000° C. or more, whereby impurity diffusion layers 52a and 52b that are self-aligned with the side walls 28a and 28b, respectively, are formed on the semiconductor substrate 21 and the buried semiconductor layers 27b.

Next, a metal film for forming silicide is formed on the semiconductor substrate 21, the buried semiconductor layers 27b, and the gate electrodes 24a and 24b by using a method such as sputtering and vapor deposition. For example, Ni, Co, W, or Mo can be used for the metal film for forming silicide.

Then, the metal film for forming silicide is caused to react with a base layer thereof by performing the thermal treatment on the semiconductor substrate 21 on which the metal film for forming silicide is formed to form silicide layers 30a, 30b, 31a, and 31b on the upper layers of the semiconductor substrate 21, the buried semiconductor layers 27b, and the gate electrodes 24a and 24b, respectively. Thereafter, the unreacted metal film is removed from the semiconductor substrate 21.

Next, as shown in FIG. 7B, inter-layer insulating layers 32 and 33 are laminated in order on the whole surface of the semiconductor substrate 21 by using a method such as the plasma CVD. For example, a silicon nitride film can be used as the material of the inter-layer insulating layer 32 and a silicon oxide film can be used as the material of the inter-layer insulating layer 33. The film thickness of the inter-layer insulating layer 32 can be set to, for example, about 60 nm, and the film thickness of the inter-layer insulating layer 33 can be set to, for example, about 400 nm.

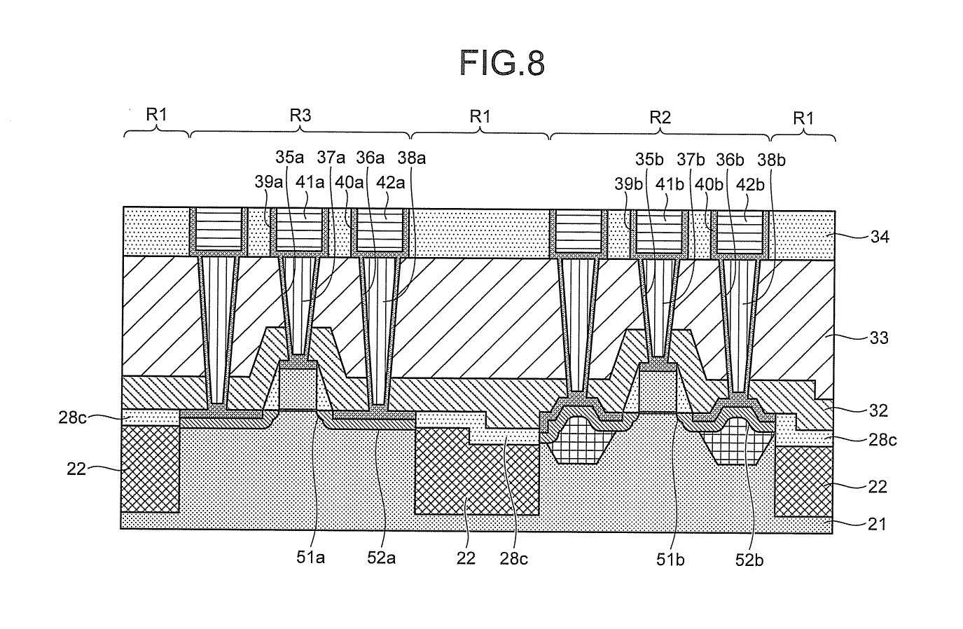

Next, as shown in FIG. 8, openings from which the silicide layers 30a, 30b, 31a, and 31b are exposed are formed in the inter-layer insulating layers 32 and 33 by using the photolithographic technique and the dry etching technique. Then, conductive films to be used as barrier metal films 35a, 35b, 36a, and 36b are formed in the inter-layer insulating layers 32 and 33 in which the openings are formed by using a method such as the sputtering as an example. Then, the openings formed in the inter-layer insulating layers 32 and 33 are filled with conductive films to be used as plug electrodes 37a, 37b, 38a, and 38b by using a method such as the thermal CVD as an example.

Then, the conductive films formed on the inter-layer insulating layer 33 are thinned until the surface of the inter-layer insulating layer 33 is exposed by using a method such as the CMP as an example, so that these conductive films are isolated for each of the silicide layers 30a, 30b, 31a, and 31b, and the plug electrodes 37a, 37b, 38a, and 38b that are connected to the silicide layers 30a, 30b, 31a, and 31b via the barrier metal films 35a, 35b, 36a, and 36b, respectively, are buried in the inter-layer insulating layers 32 and 33. As the material of the barrier metal films 35a, 35b, 36a, and 36b, for example, Ta, TaN, Ti, TiN, or a laminated structure thereof can be used. As the material of the plug electrodes 37a, 37b, 38a, and 38b, for example, a Cu, Al, W, or Sn-based material can be used. The film thickness of the barrier metal films 35a, 35b, 36a, and 36b can be set to, for example, about 5 nm.

Next, an inter-layer insulating layer 34 is laminated on the inter-layer insulating layer 33 by using a method such as the plasma CVD as an example. For example, a silicon oxide film can be used as the material of the inter-layer insulating layer 34.

Next, openings from which the plug electrodes 37a, 37b, 38a, and 38b are exposed are formed in the inter-layer insulating layer 34 by using the photolithographic technique and the dry etching technique. Then, conductive films to be used as barrier metal films 39a, 39b, 40a, and 40b are formed in the inter-layer insulating layer 34 in which the openings are formed by using a method such as the sputtering as an example. Then, the openings formed in the inter-layer insulating layer 34 are filled with conductive films to be used as wirings 41a, 41b, 42a, and 42b by using a method such as plating as an example.

Then, the conductive films formed on the inter-layer insulating layer 34 are thinned until the surface of the inter-layer insulating layer 34 is exposed by using a method such as the CMP as an example, so that these conductive films are isolated for each of the plug electrodes 37a, 37b, 38a, and 38b, and the wiring 41a, 41b, 42a, and 42b that are connected to the plug electrodes 37a, 37b, 38a, and 38b via the barrier metal films 39a, 39b, 40a, and 40b, respectively, are buried in the inter-layer insulating layer 34. As the material of the barrier metal films 39a, 39b, 40a, and 40b, for example, Ta, TaN, Ti, TiN, or a laminated structure thereof can be used. As the material of the wiring 41a, 41b, 42a, and 42b, for example, a Cu, Al, W, or Sn-based material can be used.

In the second embodiment described above, the method is explained in which the insulating layer 28 for forming the side walls 28a and 28b is used to provide the cap insulating layer 28c on the buried insulating layer 22; however, an insulating layer different from the insulating layer for forming the side walls 28a and 28b can be used as the cap insulating layer 28c.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a buried insulating layer that is buried at a position lower than a surface of the semiconductor substrate; and
a cap insulating layer that is formed on the buried insulating layer not to protrude into a shoulder portion of a step between the semiconductor substrate and the buried insulating layer and is made of a material different from the buried insulating layer.

2. The semiconductor device according to claim 1, wherein an end portion of the buried insulating layer and an end portion of the cap insulating layer are aligned with each other.

3. The semiconductor device according to claim 1, wherein an end portion of the cap insulating layer is misaligned from the step between the semiconductor substrate and the buried insulating layer by a thickness of the cap insulating layer formed on a side wall of the step between the semiconductor substrate and the buried insulating layer.

4. The semiconductor device according to claim 1, wherein a step between a surface of the semiconductor substrate and a surface of the buried insulating layer is 30 nm or more.

5. The semiconductor device according to claim 1, further comprising:
a gate electrode that is formed in an element forming region isolated by the buried insulating layer; and
a side wall that is arranged on a side wall of the gate electrode and is formed of a material same as the cap insulating layer.

6. The semiconductor device according to claim 1, wherein the cap insulating layer has a laminated structure of two or more layers.

7. The semiconductor device according to claim 1, wherein the cap insulating layer is composed of any one of a silicon nitride film, a silicon oxynitride film, a hafnium oxide film, an aluminum oxide film, an aluminum nitride film, a tantalum oxide film, a titanium oxide film, and a combination thereof.

8. The semiconductor device according to claim 1, wherein the cap insulating layer has an etch resistance higher than the buried insulating layer.

9. A method of manufacturing a semiconductor device comprising:
forming a trench in a semiconductor substrate;
burying a buried insulating layer in the trench at a position lower than a surface of the semiconductor substrate;
forming a cap insulating layer arranged to protrude into a step between the semiconductor substrate and the buried insulating layer on the buried insulating layer;
forming a resist pattern on the cap insulating layer with a step of the cap insulating layer as a boundary;
removing the cap insulating layer on the semiconductor substrate by etching the cap insulating layer with the resist pattern as a mask; and
removing the resist pattern on the semiconductor substrate after the removing the cap insulating layer on the semiconductor substrate.

10. The method according to claim 9, wherein the resist pattern is formed in a self-aligned manner with a trailing on the cap insulating layer.

11. The method according to claim 9, wherein the cap insulating layer has an etch resistance higher than the buried insulating layer.

12. The method according to claim 9, wherein a step between the surface of the semiconductor substrate and a surface of the buried insulating layer is 30 nm or more.

13. The method according to claim 12, wherein a thickness of a resist skirt remaining film of the resist pattern at the step between the semiconductor substrate and the buried insulating layer is equal to or less than a retraction amount of the surface of the buried insulating layer from the surface of the semiconductor substrate and equal to or more than 20 nm.

14. The method according to claim 10, further comprising setting an exposing condition for forming the resist pattern so that defocusing occurs at a step portion of the cap insulating layer corresponding to the step between the semiconductor substrate and the buried insulating layer is defocused.

15. A method of manufacturing a semiconductor device comprising:
forming a trench in the semiconductor substrate;
burying a buried insulating layer in the trench at a position lower than a surface of the semiconductor substrate;
forming a gate electrode in an element forming region isolated by the buried insulating layer;
forming an insulating layer, of which material is difference from the buried insulating layer, on the buried insulating layer, the insulating layer covering the gate electrode and the buried insulating layer and being arranged to protrude into a step between the semiconductor substrate and the buried insulating layer;
forming a resist pattern, which is arranged so that the element forming region is not covered, on the insulating layer with a step of the insulating layer as a boundary;
forming a cap insulating layer on the buried insulating layer and a side wall on a side face of the gate electrode by etching the insulating layer with the resist pattern as a mask; and
removing the resist pattern from the cap insulating layer.

16. The method according to claim 15, wherein the resist pattern is formed in a self-aligned manner with a trailing on the cap insulating layer.

17. The method according to claim 15, wherein the cap insulating layer has an etch resistance higher than the buried insulating layer.

18. The semiconductor device according to claim 15, wherein a step between a surface of the semiconductor substrate and a surface of the buried insulating layer is 30 nm or more.

19. The method according to claim 18, wherein a thickness of a resist skirt remaining film of the resist pattern at the step between the semiconductor substrate and the buried insulating layer is equal to or less than a retraction amount of the surface of the buried insulating layer from the surface of the semiconductor substrate and equal to or more than 20 nm.

20. The method according to claim 16, further comprising setting an exposing condition for forming the resist pattern so that defocusing occurs at a step portion of the cap insulating layer corresponding to the step between the semiconductor substrate and the buried insulating layer is defocused.
